(19) United States
(12) Patent Application Publication
(10) Pub. No.: US 2026/0076155 A1
(43) Pub. Date: Mar. 12, 2026

(54) CONFORMAL SPACER-DEFINED LINE CUT STRUCTURES

(71) Applicant: Tokyo Electron Limited, Tokyo (JP)

(72) Inventors: Eric Chih-Fang Liu, Albany, NY (US); Sophie Thibaut, Allbany, NY (US); Katie Lutker-Lee, Albany, NY (US); Steven Grzeskowiak, Albany, NY (US); Christopher Cole, Albany, NY (US); Amrit Kaphle, Albany, NY (US)

(21) Appl. No.: 18/830,309

(22) Filed: Sep. 10, 2024

(51) Int. Cl. H01L 21/033

(52) U.S. Cl. CPC H10P 76/4088; H10P 76/4083; H10P 76/4085

(57) ABSTRACT

A method of forming a line cut structure in a space separating lines of a line pattern formed in or on a substrate includes conformally depositing a conformal layer on at least one sidewall of a cut window in a resist layer and through the cut window on a portion of the space, etching the conformal layer from horizontal surfaces of the substrate leaving a cut sidewall spacer on the at least one sidewall, and removing the resist layer to form the line cut structure from the cut sidewall spacer. The method may further include forming a metal cut in a metal line by etching a dielectric layer to transfer the line pattern and the line cut structure into the dielectric layer forming a dielectric line cut structure and then forming a metal layer including the metal line in the dielectric layer.

### TECHNICAL FIELD

The present invention relates generally to semiconductor fabrication, and, in particular embodiments, methods and structures for forming line cuts in a line pattern on a substrate.

### BACKGROUND

The formation of microscale and nanoscale structures within a workpiece, such as within an integrated circuit, involves a series of processing techniques that include the formation, patterning, and removal of several layers of material on a substrate. For example, etching processes (e.g., wet etching processes or dry etching processes, whether chemical, plasma, or a combination thereof) may be used to remove exposed regions of material in the intermediate layers while a patterned layer protects unexposed regions. Although any conceivable shape may be included in the patterned layer, patterns often include basic shapes, such as blocks, lines, and holes, for example.

Line patterns (i.e., patterns that have an array of lines separated from one another by spaces) may be used in a variety of contexts, one example of which is forming metal lines (e.g., interconnects) in a metal layer of an integrated circuit. After a line pattern is transferred to material of a substrate, lines of spaces of the uniform line pattern often need to be cut (i.e., split into one or more line or space segments) to customize the functionality of the line pattern to a specific purpose. For example, metal lines of a metal layer may need to be cut in desired locations to create interconnects that electrically connect underlying devices of an integrated circuit in the desired configuration. Although originally accomplished by directly removing metal material from the substrate, metal cuts are now typically formed in a mask layer used to etch a dielectric layer in preparation for a metallization process (e.g., a damascene process).

Lithographic processes may be used to form the patterned layers that define the cut structures in a line pattern, such as for metal cuts in a metal layer. Photolithography makes up one broad category of lithographic processes. To form patterned layers using photolithography, a photosensitive layer is exposed to light through a photomask containing a two-dimensional (2D) pattern. The specific type of photolithography may be selected based on the desired feature size and includes lithography that uses visible light as well as ultraviolet (UV) lithography, deep ultraviolet (DUV) lithography, and extreme ultraviolet (EUV) lithography. As device density increases, the critical dimension (CD) limitations (i.e., resolution limitations) of lithographic processes become more and more apparent.

Therefore, improved methods and structures for forming line cuts in a line pattern on a substrate that overcome the limitations of conventional lithographic processes are desirable.

### SUMMARY

In accordance with an embodiment of the invention, a method of forming a line cut structure in a space separating lines of a line pattern formed in or on a substrate includes conformally depositing a conformal layer on at least one sidewall of a cut window in a resist layer and through the cut window on a portion of the space, etching the conformal layer from horizontal surfaces of the substrate leaving a cut sidewall spacer on the at least one sidewall, and removing the resist layer to form the line cut structure from the cut sidewall spacer. The at least one sidewall spans the space separating the lines of the line pattern.

In accordance with another embodiment of the invention, a method of forming a metal cut in a metal line includes conformally depositing, using an ALD process, a conformal layer on at least one sidewall of a cut window in a resist layer and through the cut window on a portion of a space separating lines of a line pattern formed in or on a substrate, etching the conformal layer from horizontal surfaces of the substrate leaving a cut sidewall spacer on the at least one sidewall, removing the resist layer to form a line cut structure from the cut sidewall spacer, etching a dielectric layer to transfer the line pattern and the line cut structure into the dielectric layer forming a dielectric line cut structure, and forming a metal layer including the metal line in the dielectric layer. The at least one sidewall spans the space separating the lines of the line pattern. The dielectric line cut structure forms the metal cut in the metal line.

In accordance with still another embodiment of the invention, an integrated circuit includes a substrate that includes a device layer, a metal layer formed over the device layer, and a dielectric line cut structure forming a metal cut dividing a metal line of a plurality of metal lines of the metal layer into a first metal segment and a second metal segment. The plurality of metal lines that are separated by dielectric material. The first metal segment has a first line thickness and the second metal segment has a second line thickness that is less than the first line thickness.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B schematically illustrate an example process including a line cut structure spanning a space of a line pattern formed from a sidewall spacer of a window through a resist layer where FIG. 1A shows a deposition of a conformal layer and FIG. 1B shows an etch to form the sidewall spacer and a removal of the resist layer to form the line cut structure in accordance with embodiments of the invention;

FIGS. 2A and 2B schematically illustrate an example process including a window with a sidewall spanning a space of a line pattern formed through a resist layer where FIG. 2A shows a formation of the resist layer over the line pattern and FIG. 2B shows a development and etch of the resist layer to form the window in accordance with embodiments of the invention;

FIGS. 3A and 3B schematically illustrate an example process including a metal cut formed in a metal line using a line cut structure formed from a sidewall spacer where FIG. 3A shows a mandrel pull leaving behind line spacers and line cut structures and FIG. 3B shows an etch and metallization of an underlying dielectric layer to form a metal layer containing the metal cut in the metal line in accordance with embodiments of the invention;

FIG. 4A-4C schematically illustrate another example process including metal cuts formed metal lines using line cut structures formed from a sidewall spacer where FIG. 4A shows the formation of a window through a resist layer overlying a line pattern, FIG. 4B shows the formation of line cut structures from sidewall spacers conformally deposited on sidewalls of the window, and FIG. 4C shows the formation of metal cuts in metal lines of a metal layer by transferring the line cut structures to an underlying dielectric layer in accordance with embodiments of the invention;

FIG. 5 schematically illustrates an example process including a metal cut formed in a metal line using a line cut structure formed from a sidewall spacer where two cut windows are formed through a resist layer overlying a line pattern in accordance with embodiments of the invention;

FIG. 6 schematically illustrates an example process including a metal cut formed in a metal line using a line cut structure formed from a sidewall spacer where spacers spanning spaces of a line pattern are formed on two sidewalls of a cut window formed through a resist layer overlying the line pattern in accordance with embodiments of the invention;

FIG. 7 schematically illustrates an example process including a metal cut formed in a metal line using a line cut structure formed from a sidewall spacer where a cut window spanning only one space of a line pattern is formed through a resist layer overlying the line pattern in accordance with embodiments of the invention;

FIG. 8 schematically illustrates an example process including a metal cut formed in a metal line using a line cut structure formed from a sidewall spacer where a cut window is formed through a resist layer overlying a line pattern that does not include preexisting sidewalls spacers in accordance with embodiments of the invention;

FIG. 9 illustrates a flowchart of an example method of forming a line cut structure that may be implemented by processes including a line cut structure spanning a space of a line pattern formed from a sidewall spacer of a window through a resist layer in accordance with embodiments of the invention; and

FIG. 10 illustrates a flowchart of an example method of forming a metal cut that may be implemented by processes including a line cut structure spanning a space of a line pattern formed from a sidewall spacer of a window through a resist layer in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Lines or spaces may need to be divided into segments at desired locations in a line pattern that has already been formed (e.g., that will be used as a mask for transferring the pattern to an underlying layer). One application of such a technique is during a metal cut process to create metal line segments in a metal layer of an integrated circuit. In current technology nodes, metal cuts are typically done using EUV lithography. However, this application of EUV lithography is subject to fundamental issues regarding the metal cut CD, including tip-to-tip (T2T) CD variation and local CD uniformity (LCDU) control issues (e.g., the measure of how consistent the CDs, like line width or space width, are within a die or a small area on the wafer).

For example, EUV lithography has undesirably large local CD variation, such as several nanometers, but at least a couple of nanometers. In the context of metal cuts, this results in an undesirably high risk of gap filling during metal cut processes (i.e., T2T CD variation allows gap between tips of adjacent metal lines to be filled causing unintended electrical shorts in the integrated circuit). That is, T2T CD variation can often be the failure mode for creating the electrical shorts leading to critical yield and reliability issues.

One specific example of a conventional metal cut process is a tone inversion process during which cuts patterned using lithography (e.g., UV lithography) are filled with material that remains after an etch back procedure. The T2T CD control of conventional tone inversion metal cut processes is still undesirably coarse (e.g., the minimum T2T average CD is limited to 10 nm with an LCDU (3σ variation) greater than 3 nm). Moreover, conventional tone inversion metal cut processes are still prone to void and filling issues. Further, in addition to limitations regarding CD and CD variation, the tone inversion process has many other drawbacks, such as adding additional processing steps and additional complication to the metal cut process.

In accordance with embodiments herein described, the invention proposes using a conformal spacer approach to enable the formation of “line cut” structures dividing spaces of a line pattern into segments. For example, the line cut structures may be subsequently used as part of an etch mask for transferring the structures into a dielectric material to form metal cuts in a metal layer, which may be subsequently formed by a metallization process, such as a damascene process.

Specifically, in various embodiments, a “cut” lithography pattern with one or more relatively large blocks (e.g., with relaxed resolution and/or alignment requirements compared to conventional lithography techniques used for form metal cuts) is formed over a line pattern that includes multiple lines separated by spaces (i.e., physical line structures formed in or on the substrate). For example, the line pattern may include mandrels and existing sidewall spacers. Each block is configured to be a “cut window” through the resist material of the cut lithography pattern that exposes a portion of at least one space of the line pattern to a subsequent processing step. That is, at least one sidewall of the cut window spans the space (or in many cases multiple spaces) to divide the space(s) into segments. Of course, the cut lithography pattern may already be present on the substrate in some embodiments.

A conformal deposition process, such as an atomic layer deposition (ALD) process, is then used to deposit spacer material on the resist material to form “cut” sidewall spacers on sidewalls of the cut window(s) including on sidewalls that extend across (i.e., span) the space(s) of the line pattern. The cut sidewall spacers are new sidewall spacers, in contrast to sidewall spacers that may already exist on the substrate, such as previously formed on mandrels of the line pattern that will later define dielectric lines between metal lines, as one specific example (“line” sidewall spacers).

The resist material is then removed to form one or more line cut structures from the cut sidewall spacers. Advantageously, the thickness of the cut sidewall spacers, which becomes the T2T CD of the line cut structures, is well-controlled by virtue of the conformal deposition process (as opposed to the CD of the lithographic process). Moreover, the line cut structures (which are at this point structures formed out of the spacer material) may then be used to form subsequent well-controlled structures, such as a well-controlled metal cuts in a metal layer.

The method of forming a line cut structure may be incorporated into any desired process flow, such as part of a longer process to form other structures on the substrate. For example, the method of forming a line cut structure may be part of a process to form a metal layer that includes one or more metal cuts defined by the line cut structure(s), such as by etching a dielectric layer to transfer a line pattern including the line cut structure(s) into the dielectric layer to form a dielectric line pattern with dielectric line cut structure(s) and then forming a metal layer in the dielectric layer. For example, the metal layer may be formed in the dielectric layer using a damascene process, which may be followed by a planarization process, such as a chemical mechanical polish (CMP) process. The spaces of dielectric line pattern are at least partially filled with metal forming metal lines with the dielectric line cut structure(s) forming metal cut(s) in one or more of the metal lines.

Similarly, the method may also include one or more process steps before conformally depositing the spacer material, such as lithography steps to form the cut window(s) in the cut lithography pattern and lithography steps to form the line pattern on the substrate, as well as spacer formation steps, such to form line sidewall spacers when the line pattern are mandrels, for example. Of course, where a process begins and ends depends on the definition of the process, and the method may also include additional process steps before and after those explicitly described, as may be apparent to those of skill in the art.

The embodiment methods of forming line cuts in a line pattern described herein may advantageously avoid using direct EUV patterning to form line cut structures (e.g., to subsequently form metal cuts in a metal layer). This may result in many advantages compared to conventional processes that use direct lithography to define cut structures, such as conventional tone inversion metal cut processes. For example, the embodiment methods may have the advantage of reducing or eliminating the risk of gap filling during a metal cut process, such as by improving T2T CD variation to less than a nanometer (<1 nm).

The embodiment methods may also have the benefit of reducing the number of processing steps and/or process complexity in comparison to conventional processes, such as conventional tone inversion processes. Since the CD of the embodiment line cut structures is advantageously controlled by a conformal deposition method, the resolution and/or CD requirements of the lithographic processes used to create the large blocks may be relaxed compared to conventional processes that use UV or EUV lithography. Yet, the average minimum T2T CD of resulting line cuts (e.g., metal cuts) and T2T CD variation may still be better than conventional processes even with this reduction in cost and complexity.

The embodiment methods of forming line cuts may also have unique structural advantages over conventional processes. For example, two different spacer materials may be used during the formation of the line cut structures allowing flexibility in both the selection of the materials and aspects of the structures that are formed. For example, in the context of forming metal cuts in a metal layer, the dielectric line CD and the metal cut CD may be different. Further, the embodiment methods may result in two different dielectric line CDs in the region of the metal cuts. Additionally, the dielectric line CD may be different from conventional processes (such as conventional self-aligned processes, for example).

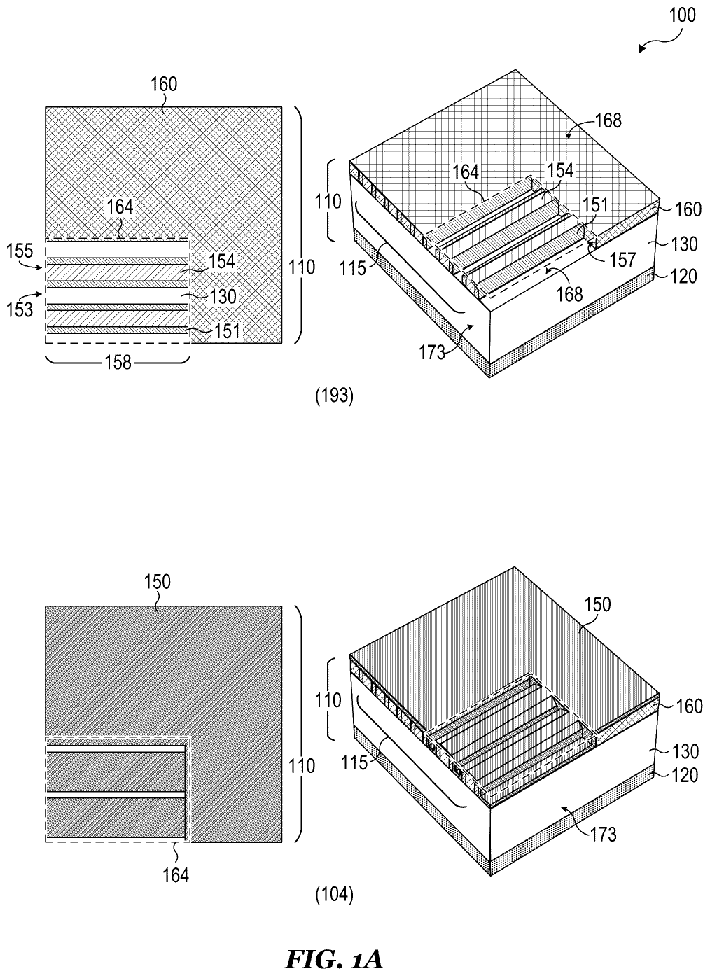

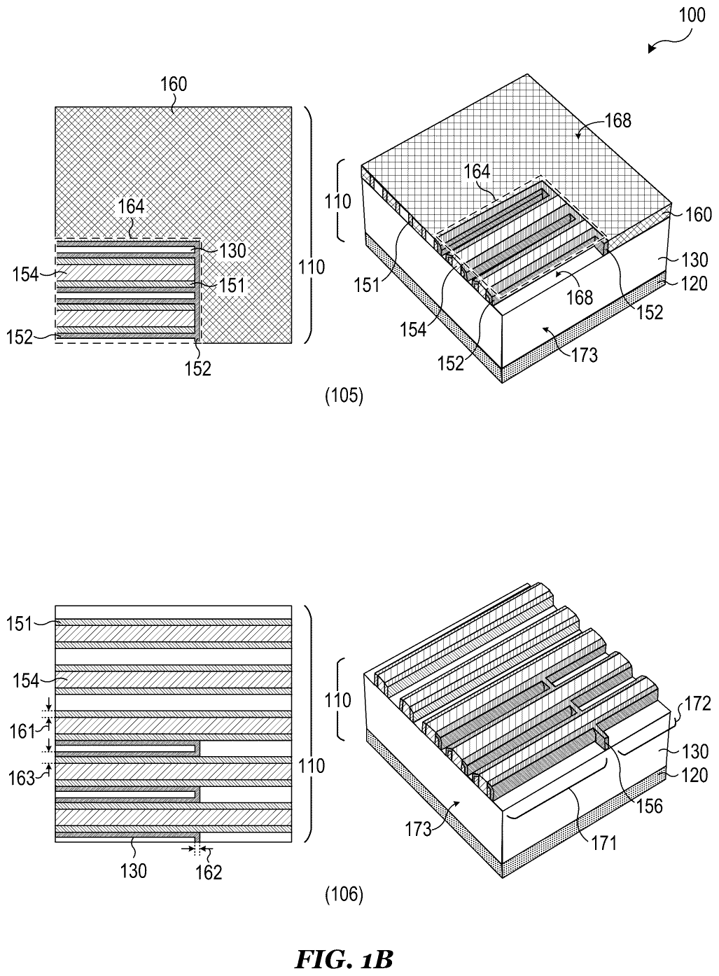

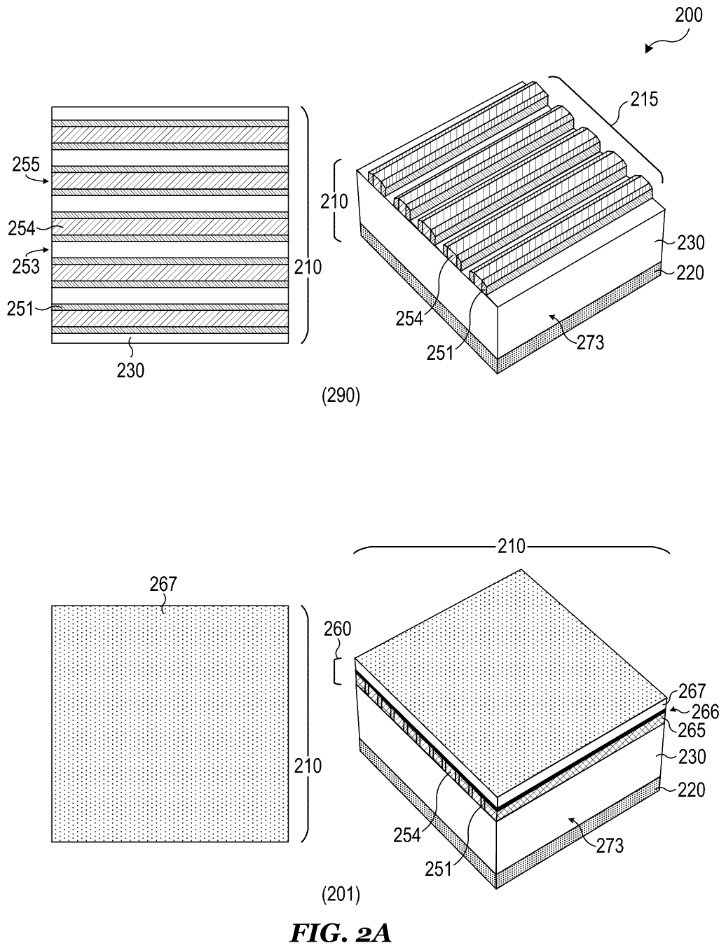

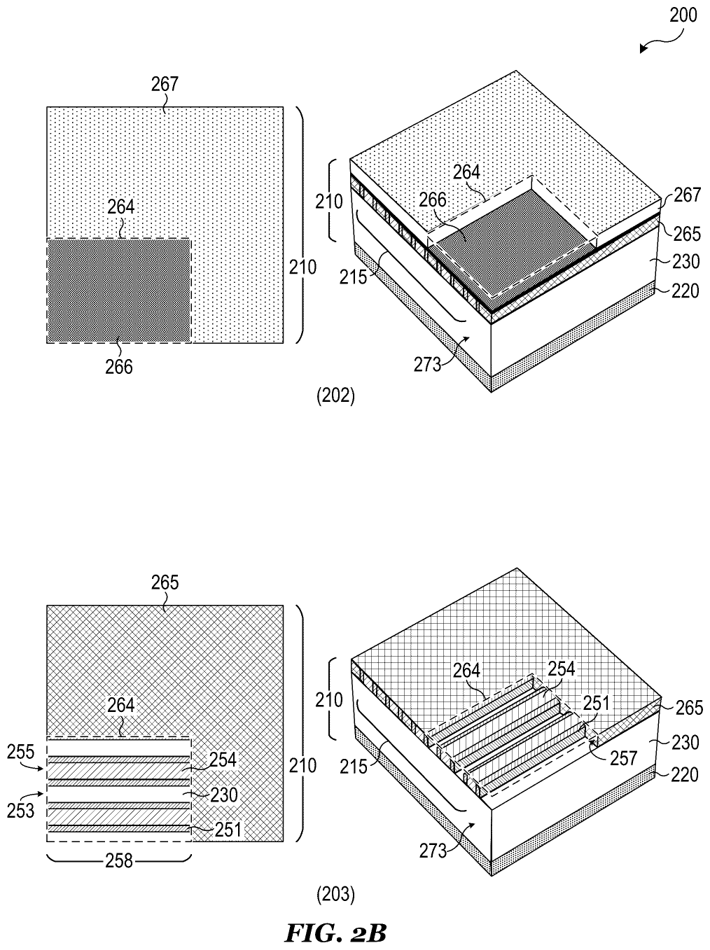

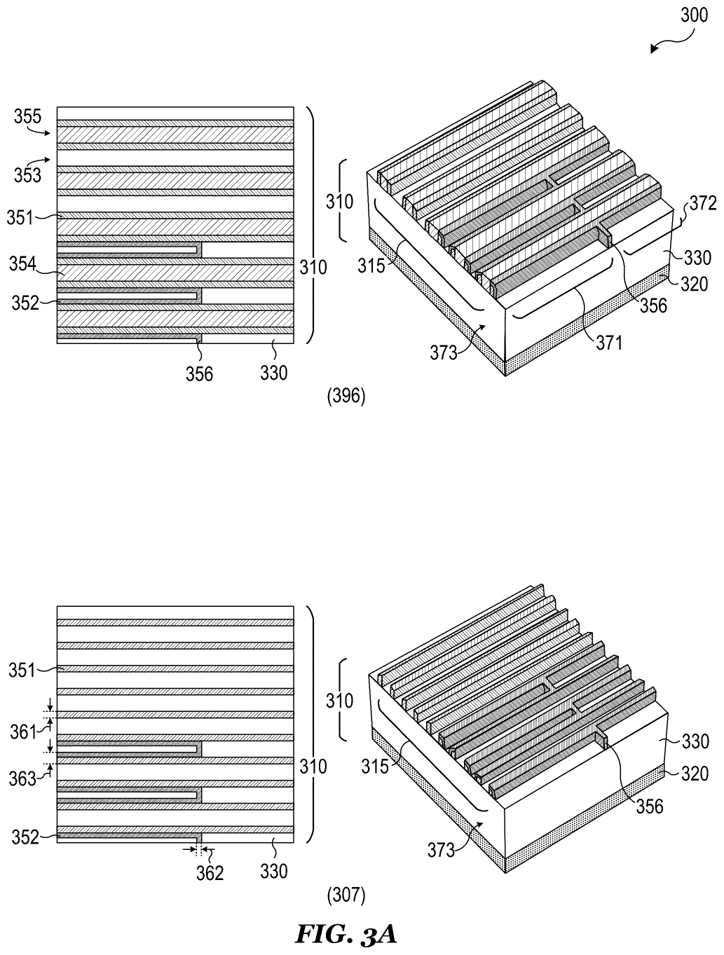

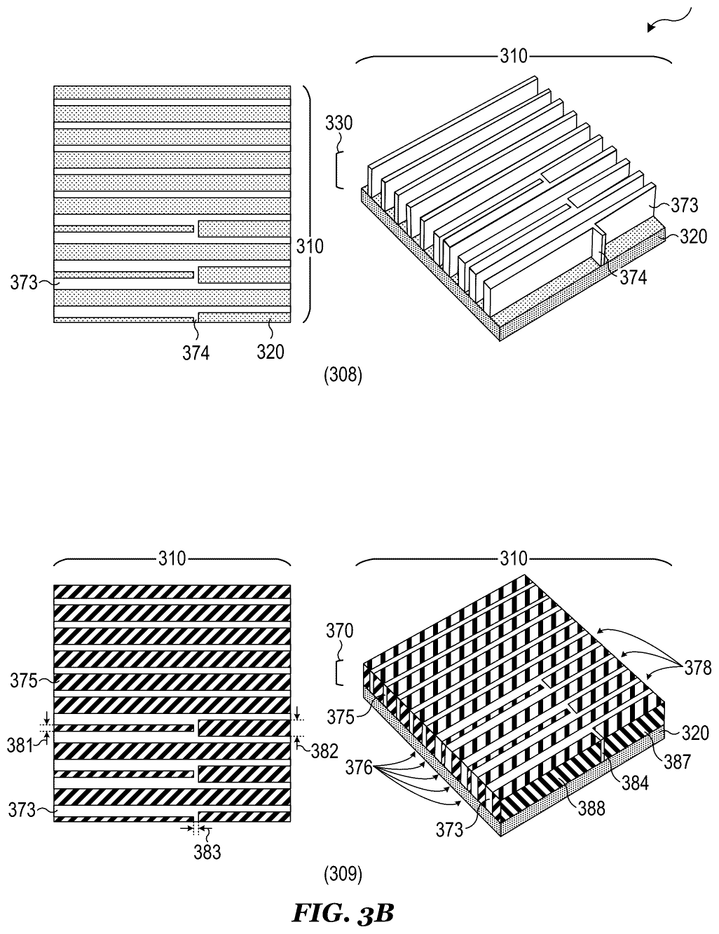

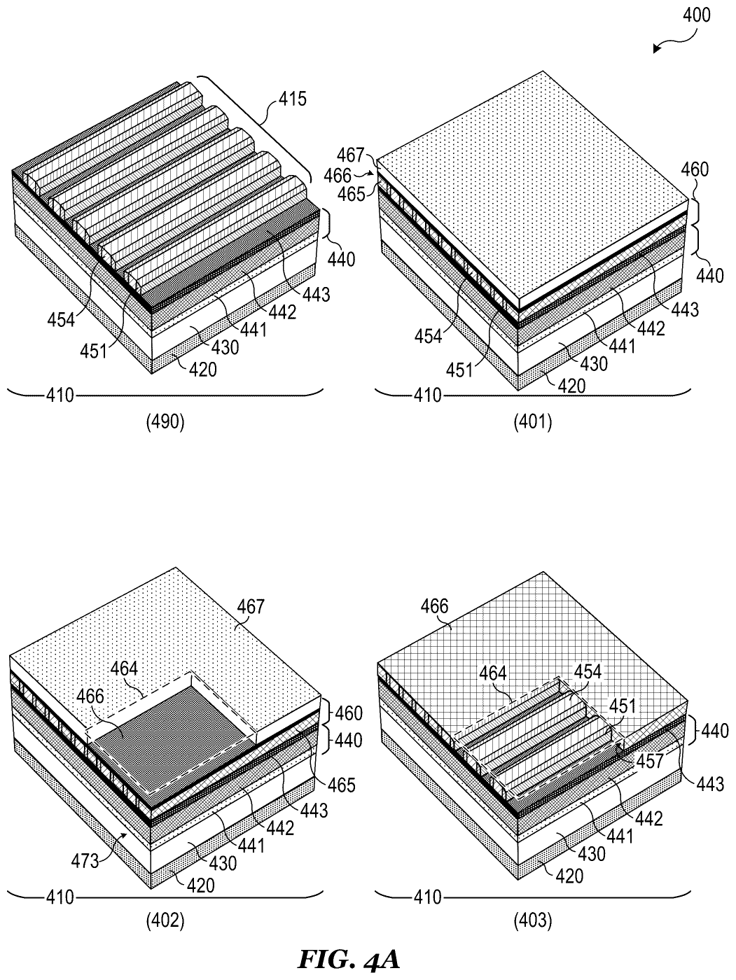

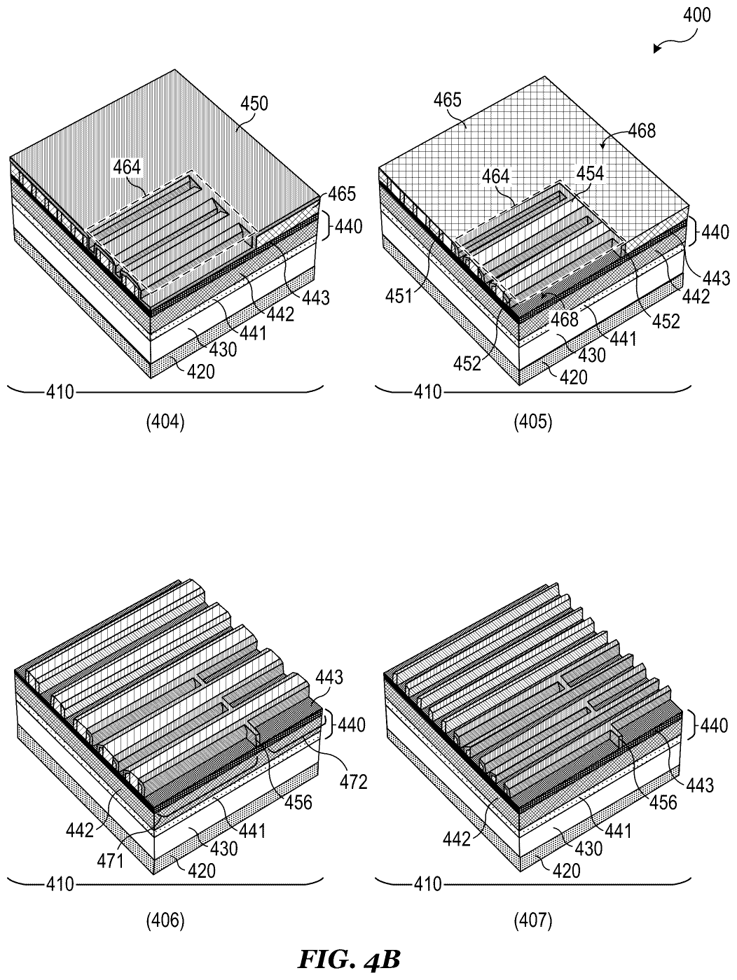

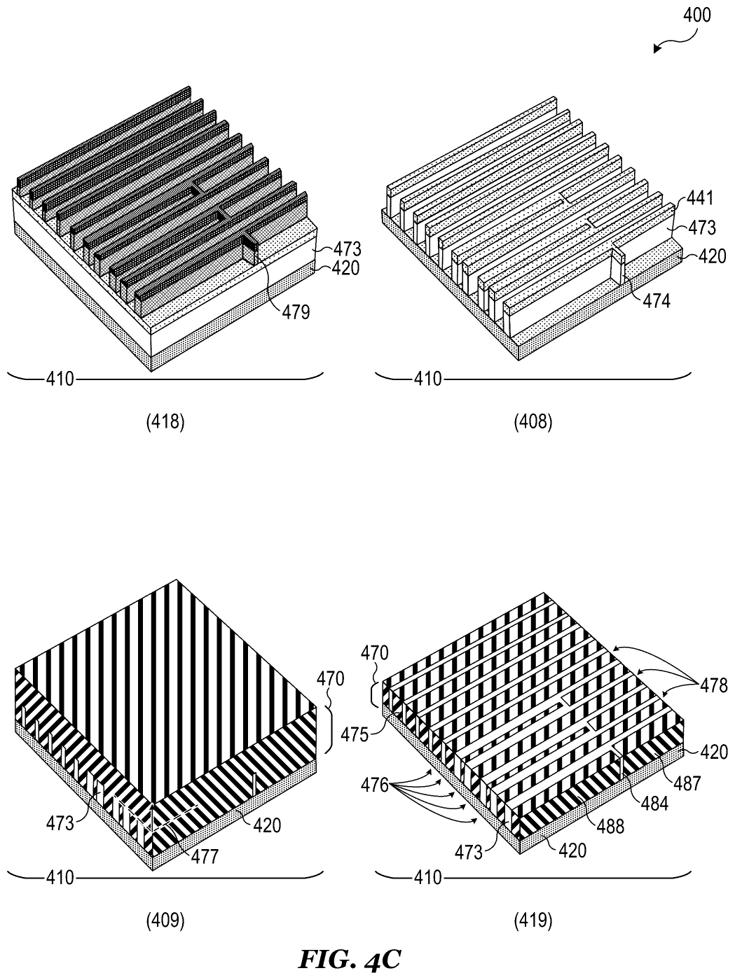

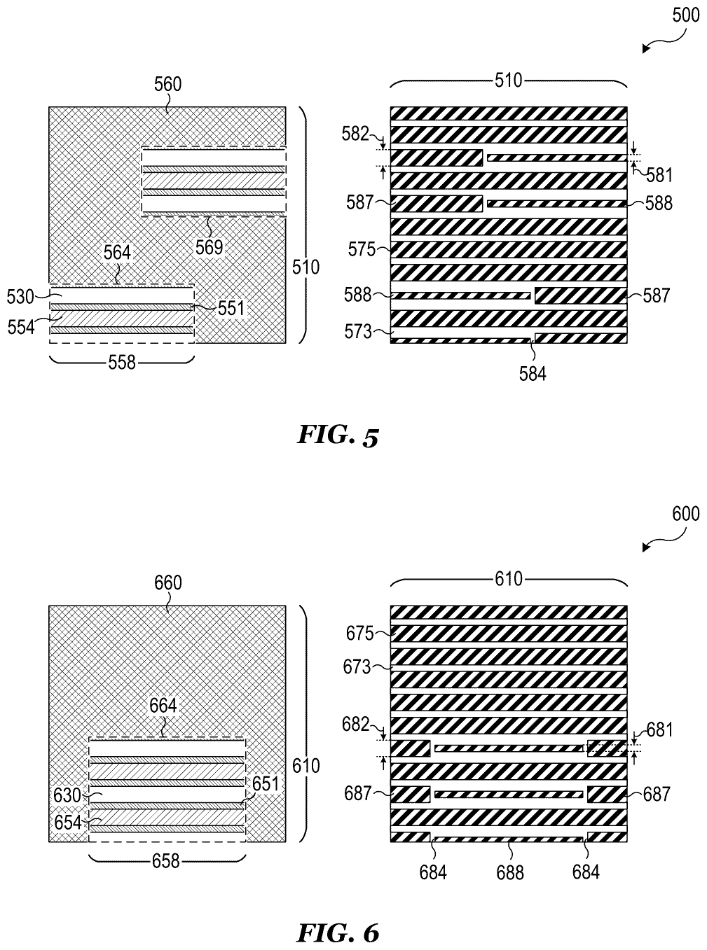

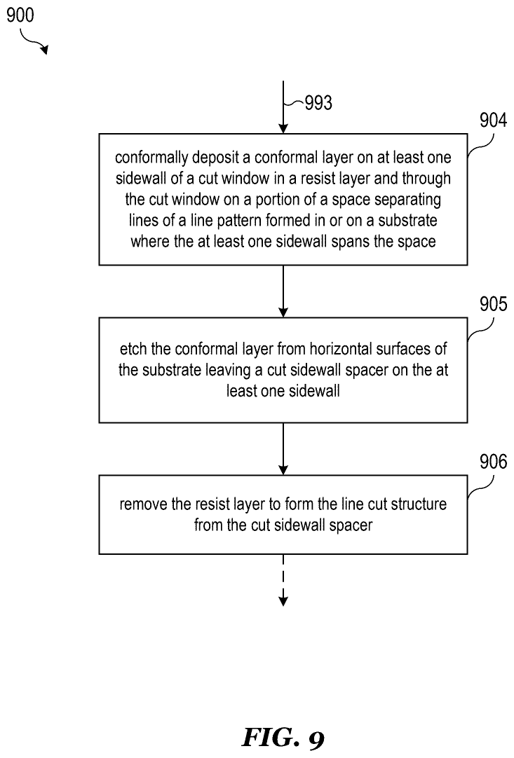

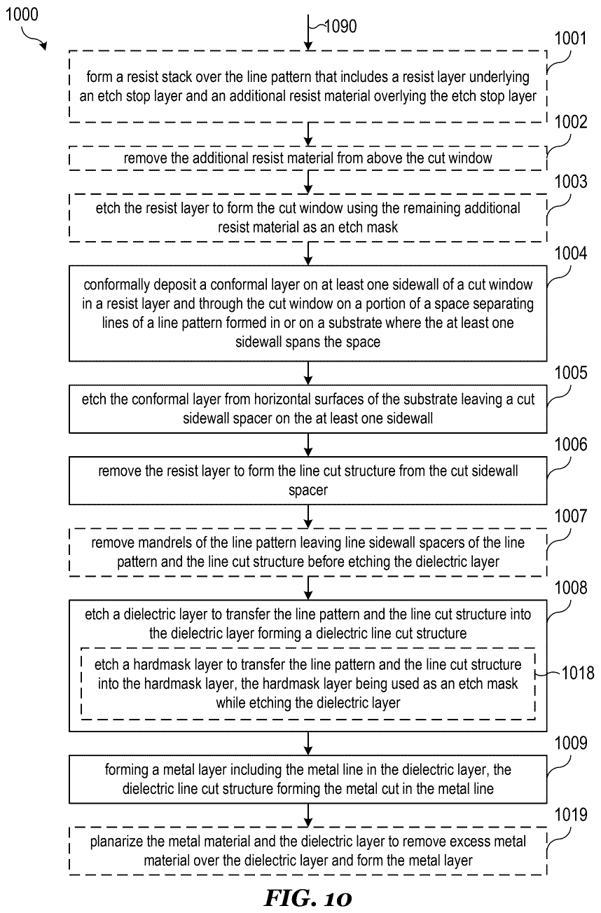

Embodiments provided below describe various methods and structures for forming line cuts in a line pattern on a substrate, and in particular embodiments, to methods and structures for forming line cut structures spanning spaces of a line pattern formed from sidewall spacers of one or more windows through a resist layer. The following description describes the embodiments. FIGS. 1A and 1B are used to describe an example process including a line cut structure, FIGS. 2A and 2B are used to described an example process including a window though a resist layer, and FIGS. 3A and 3B are used to described an example process including a metal cut in a metal line. Another example process including a window, a line cut structure, and a metal cut is described using FIG. 4A-4C. Four more example processes are described using FIG. 5-8. Two example methods are described using FIGS. 9 and 10.

FIGS. 1A and 1B schematically illustrate an example process including a line cut structure spanning a space of a line pattern formed from a sidewall spacer of a window through a resist layer where FIG. 1A shows a deposition of a conformal layer and FIG. 1B shows an etch to form the sidewall spacer and a removal of the resist layer to form the line cut structure in accordance with embodiments of the invention.

Referring to FIG. 1A, a process 100 begins with a substrate 110 in an initial state 193 where a line pattern 115 that includes lines 155 separated by spaces 153 has been formed over a dielectric layer 130 (including a dielectric material 173, but which may also include additional materials) that overlies an underlying layer 120. A window resist layer 160 has been formed over the line pattern 115 and a cut window 164 has been removed from the window resist layer 160 to expose a portion of the line pattern 115. Specifically, a portion of a space 158 (here a portion of at least three of the spaces 153) and portions of the lines 155 have been exposed by the cut window 164, which includes a window sidewall 157 that spans at least one of the spaces 153.

The dielectric layer 130 includes the dielectric material 173, which may be any dielectric material, but is a low-κ dielectric material in some embodiments. The underlying layer 120 may be any material or combination of materials, such as a device layer of an integrated circuit formed in a semiconductor material, for example. The window resist layer 160 may be any suitable resist material, such as a photoresist material sensitive to specific wavelength, like a UV photoresist, a DUV photoresist, an EUV photoresist, etc. The window resist layer 160 may also be a stack of materials. In some embodiments, the window resist layer 160 (or at least the top layer of the window resist layer 160) is a lower resolution photoresist that than used to pattern the line pattern 115. For example, the window resist layer 160 is a UV photoresist in one embodiment, which may be made possible by the relaxed dimensional requirements of the cut window 164 compared to the pitch of the line pattern 115.

Although this does not have to be the case, in this specific example, the lines 155 of the line pattern 115 are formed from mandrels 154 that have line sidewall spacers 151 formed thereon. In the initial state 193, the window resist layer 160 and the dielectric layer 130 have horizontal surfaces 168 that are exposed to subsequent processing steps. During a conformal deposition 104, a conformal layer 150 is deposited on all exposed surfaces of the substrate 110, which in this case include the dielectric layer 130, the line sidewall spacers 151, the mandrels 154, and the window resist layer 160. For example, the conformal deposition 104 may be a well-controlled conformal deposition process, such as an ALD process that allows the thickness of the conformal layer 150 to be tightly controlled.

The conformal layer 150 may cover exposed surfaces with a substantially uniform thickness (e.g., at least tops and sides of the features, and can also cover bottoms of features in some cases) A wide variety of materials may be used for the conformal layer 150, such as spacer materials like silicon-based materials, metal-based materials, and others. In one embodiment, the conformal layer 150 is titanium oxide. Other possible materials include silicon oxide, silicon nitride, silicon oxynitride, amorphous silicon, and silicon carbide (which may be considered silicon-based materials), zinc oxide, tin oxide, indium oxide, titanium oxide, and aluminum oxide (which may be considered metal-based materials, or, more specifically, metal oxide materials), titanium nitride, aluminum nitride, and tantalum nitride (which may be considered metal-based materials, or, more specifically, metal nitride materials) and others.

Referring now to FIG. 1B, the process 100 continues with a cut spacer etch 105 that removes the conformal layer 150 from the horizontal surfaces 168 and leaves cut sidewall spacers 152 on sidewalls of the window resist layer 160 as well as sidewalls of the lines 155 (which are the line sidewall spacers 151 in this case). For example, the cut spacer etch 105 may use an anisotropic etching process, such as a reactive ion etching (RIE) process. Various etch chemistries may be employed (and may depend on the specific material of the conformal layer 150). One example of an etch chemistry that may be used during the cut spacer etch 105 is a chlorine-based etch chemistry.

Then, in a resist removal process 106 (e.g., an ashing process), the window resist layer 160 is removed leaving behind the line pattern 115 and the cut sidewall spacers 152 which have now been formed in desired spaces 153 of the line pattern 115. The resist removal process 106 is configured to selectively remove the window resist layer 160 and may include an oxygen treatment. For example, the resist removal process 106 may use plasma excited from an oxygen-containing gas, such as O₂ gas.

In one embodiment, the material of the cut sidewall spacers 152 is the same as the material of the line sidewall spacers 151. However, this does not have to be the case. In other embodiments, the material composition of the cut sidewall spacers 152 is different than that of the line sidewall spacers 151. Using different materials for the cut sidewall spacers 152 and the line sidewall spacers 151 may result in an etch rate difference between the two that may advantageously allow for independent control in the following transferring process. For example, in one embodiment, the line sidewall spacers 151 are silicon oxide and the cut sidewall spacers 152 are titanium oxide. During the dielectric etch of the dielectric layer 130, the etch rate of the line cut spacers 151 may then be faster than that of the cut sidewall spacers 152 so that the metal cut CD is substantially maintained while the metal line CD is increased.

The cut sidewall spacers 152 span respective spaces of the line pattern 115 forming line cut structures 156 that separate each spanned space into a first space segment 171 and a second space segment 172. The line cut structures 156 may then be used in any desired way during subsequent processing. By virtue of the spacer formation process used to form the line cut structures 156, the CD of the line cut structures 156 is controlled by the thickness of the conformal layer 150, which becomes the cut spacer thickness 162. Additionally, since the line sidewall spacers 151 are partially exposed through the cut window 164, the line spacer thickness 161 is added to the cut spacer thickness 162 in the cut window 164 becoming a combined thickness 163 that narrows the space segments in this region.

FIGS. 2A and 2B schematically illustrate an example process including a window with a sidewall spanning a space of a line pattern formed through a resist layer where FIG. 2A shows a formation of the resist layer over the line pattern and FIG. 2B shows a development and etch of the resist layer to form the window in accordance with embodiments of the invention. The process of FIGS. 2A and 2B may be used in conjunction with or be a specific implementation of other processes described herein such as the process of FIGS. 1A and 1B, for example. Similarly labeled elements may be as previously described.

Referring to FIG. 2A, a process 200 begins with a substrate 210 in an initial state 290 where a line pattern 215 that includes lines 255 separated by spaces 253 has been formed over a dielectric layer 230 (including a dielectric material 273) that overlies an underlying layer 220. It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system.

As before, the lines 255 of the line pattern 215 are formed from mandrels 254 that have line sidewall spacers 251 formed thereon. During a resist formation step 201, a window resist layer 260 is formed over the line pattern 215 and the dielectric layer 230, as shown. In various embodiments, the resist formation step 201 is a “coarse” lithography pattern relative to the line pattern 215, for example. The window resist layer 260 may be a single layer in some embodiments. In this specific example, the window resist layer 260 includes three layers: a lower window material layer 265 (e.g., a non-photosensitive material, for example) and an upper window resist layer 267 (e.g., a photosensitive material, such as a UV photoresist material, for example) with a window etch stop layer 266 formed therebetween.

Now turning to FIG. 2B, the process 200 continues with a resist develop 202 that removes a portion of the resist material of the upper window resist layer 267 above what will become a cut window 264 exposing the window etch stop layer 266. It should be noted that, unlike conventional methods, the resist develop 202 is only for the location of a future line cut and does not control the CD of the cut itself. After the resist develop 202, the lower window material layer 265 is etched during a window etch 203 using the upper window resist layer 267 as an etch mask to form the cut window 264 with a window sidewall 257 spanning at least one of the spaces 253 and exposing a portion of a space 258 (or more than one space, as shown here).

Although the details of the window etch 203 may vary depending on the specific details of a given application, the window etch stop layer 266 may remain in regions outside the cut window 264 after the window etch 203 and may be removed to leave the lower window material layer 265, as shown. At this stage, the process 200 may continue with the formation of line spacer structures, such as using the process 100 of FIGS. 1A and 1B, for example.

FIGS. 3A and 3B schematically illustrate an example process including a metal cut formed in a metal line using a line cut structure formed from a sidewall spacer where FIG. 3A shows a mandrel pull leaving behind line spacers and line cut structures and FIG. 3B shows an etch and metallization of an underlying dielectric layer to form a metal layer containing the metal cut in the metal line in accordance with embodiments of the invention. The process of FIGS. 3A and 3B may be used in conjunction with or be a specific implementation of other processes described herein such as the process of FIGS. 1A and 1B, for example. Similarly labeled elements may be as previously described.

Referring to FIG. 3A, a process 300 begins with a substrate 310 in an initial state 396 where a line pattern 315 that includes lines 355 separated by spaces 353 (here formed from mandrels 354 with line sidewall spacers 351 formed thereon) has been formed over a dielectric layer 330 (including a dielectric material 373) that overlies an underlying layer 320. In this specific example, cut sidewall spacers 352 have also already been formed, including line cut structures 356 that separate some of the spaces 353 of the line pattern 315 into a first space segment 371 and a second space segment 372. For example, the line cut structures 356 may have been formed using a process similar to the process 100 of FIGS. 1A and 1B.

A mandrel pull 307 is performed on the substrate 310 in the initial state 396 and the mandrels 354 are removed from between the line sidewall spacers 351 (which increases the number of spaces of the line pattern 315) leaving being the line sidewall spacers 351 and the cut sidewall spacers 352 including the line cut structures 356. As shown, the separation between spaces of the line pattern 315 are the line spacer thickness 361 in some places and are a combined thickness 363 equal to the sum of the line spacer thickness 361 and the cut spacer thickness 362 in other places. Additionally, the width of the line cut structures 356 is still defined as the cut spacer thickness 362 after the mandrel pull 307.

Now referring to FIG. 3B, the process 300 continues with a dielectric etch 308 (e.g., a low-κ dielectric etch) that transfers the line pattern 315 into the dielectric layer 330 including the line cut structures 356, which become dielectric line cut structures 374. A metal layer 370 is then formed in the dielectric layer 330 during a metallization 309 that fills the empty regions of the dielectric layer 330 with a metal material 375 (e.g., copper using a damascene process, but other metals and metallization processes may also be used). The pattern of the metal layer 370 includes metal cuts 384 that separate respective metal lines 376 into a first metal segment 388 and a second metal segment 387. Notably, the CD of the metal cuts 384 is desirably small and controlled by the cut spacer thickness 362, resulting in the metal cut thickness 383. Also notable, is the absence of the metal cuts 384 in some of the metal lines 376, which is the case in this specific example because of the use of the mandrels 354. Specifically, the metal cuts 384 that are aligned with one another are separated by metal lines that do not have metal cuts (the mandrel metal lines 378).

The well-controlled CD of the metal cuts 384 may advantageously result improved T2T CD compared to conventional metal cut methods. For example, the metal cuts 384 may have a T2T CD that is less than about 10 nm in one embodiment. The variation of the T2T CD may also be improved. In one embodiment, the T2T CD variation of the metal cuts 384 is less than about 1 nm. For example, conventional methods may be unable to reach T2T CD of 10 nm and below, with T2T CD variation being greater than 3 nm in 3σ. The embodiment processes described herein may advantageously enable T2T CD control at 10 nm and below including improved T2T CD variation of less than 1 nm in 3σ.

The use of the cut sidewall spacers 352 also changes the thickness of the metal lines 376 that are cut by the metal cuts 384. For example, the first metal segments 388 have a first line thickness 381 that is thinner because the first metal segments 388 are separated from other metal lines by dielectric material 373 resulting from the combination of the line sidewall spacers 351 and the cut sidewall spacers 352. Meanwhile, the second metal segments 387 have a second line thickness 382 that is the same thickness as the other metal lines 376 because the second metal segments 387 are separated from other metal lines only be the dielectric material 373 resulting from the line sidewall spacers 351.

FIG. 4A-4C schematically illustrate another example process including metal cuts formed metal lines using line cut structures formed from a sidewall spacer where FIG. 4A shows the formation of a window through a resist layer overlying a line pattern, FIG. 4B shows the formation of line cut structures from sidewall spacers conformally deposited on sidewalls of the window, and FIG. 4C shows the formation of metal cuts in metal lines of a metal layer by transferring the line cut structures to an underlying dielectric layer in accordance with embodiments of the invention. The process of FIG. 4A-4C may be used in conjunction with or be a specific implementation of other processes described herein such as the processes of FIG. 1A-3C, for example. Similarly labeled elements may be as previously described.

Referring to FIG. 4A, a process 400 begins with a substrate 410 in an initial state 490 where a line pattern 415 that includes lines separated by spaces has been formed over a mask stack 440, a dielectric layer 430 (including a dielectric material 473), and an underlying layer 420. As before, the lines of the line pattern 415 are formed from mandrels 454 that have line sidewall spacers 451 formed thereon. The mask stack 440 may include various layers, such as etch stop layers or hardmask layers. In this specific example, the mask stack 440 has three layers: a mandrel etch stop layer 443 (which may have been used to form the line sidewall spacers 451), a hardmask etch stop layer 441, and a hardmask layer 442 formed therebetween.

The hardmask layer 442 may be various materials. In various embodiments, the hardmask layer 442 is metal-based, and is tungsten-containing in some embodiments. In one embodiment, hardmask layer 442 includes tungsten silicide. In another embodiment, the hardmask layer 442 is pure tungsten. In another embodiment, the hardmask layer 442 is include titanium oxide. As before the mandrel etch stop layer 443 may include various materials, such as oxides or nitrides, and is silicon oxide in one embodiment. The hardmask etch stop layer 441 may be a silicon-based material (which may enhance the adhesion between the hardmask layer 442 and the dielectric layer 430). In one embodiment, the hardmask etch stop layer 441 is silicon oxide. In another embodiment, the hardmask etch stop layer 441 is silicon nitride. In still another embodiment, the hardmask etch stop layer 441 is silicon oxynitrides.

During a resist formation step 401, a window resist layer 460 is formed over the line pattern 415 and the dielectric layer 430, which includes three layers: a lower window material layer 465 and an upper window resist layer 467 with a window etch stop layer 466 formed therebetween. A portion of the resist material of the upper window resist layer 467 above what will become a cut window 464 is removed during a resist develop 402 exposing the window etch stop layer 466.

Then, during a window etch 403, the lower window material layer 465 is etched using the upper window resist layer 467 as an etch mask to form the cut window 464 with a window sidewall 457 spanning at least one of the spaces. Although the details of the window etch 403 may vary depending on the specific details of a given application, the window etch stop layer 466 may remain in regions outside the cut window 464 after the window etch 403, as shown and may be removed prior to a subsequent step.

Referring to FIG. 4B, the process 400 continues with a conformal deposition 404 (e.g., an ALD process), during which a conformal layer 450 is deposited on all exposed surfaces of the substrate 410. A cut spacer etch 405 is then performed that removes the conformal layer 450 from the horizontal surfaces 468 and leaves cut sidewall spacers 452 on sidewalls of the lower window material layer 465 as well as sidewalls of the lines (which are the line sidewall spacers 451 in this case). Then, in a resist removal process 406 (e.g., an ashing process), the lower window material layer 465 is removed leaving behind the line pattern 415 and the cut sidewall spacers 452 which have now been formed in desired spaces of the line pattern 415 as line cut structures 456. The cut sidewall spacers 452 span respective spaces of the line pattern 415 forming line cut structures 456 that separate each spanned space into a first space segment 471 and a second space segment 472. A mandrel pull 407 is then performed to remove the mandrels 454 from between the line sidewall spacers 451.

Referring to FIG. 4C, the process 400 continues with a hardmask etch 418 that transfers the line pattern 415 (which does not include the mandrels 454, but does include the line sidewall spacers 451, the cut sidewall spacers 452, and the line cut structures 456) through the mandrel etch stop layer 443 and into the hardmask layer 442 forming hardmask line cut structures 479. The hardmask etch 418 may stop at the hardmask etch stop layer 441. The hardmask layer 442 may then be used as an etch mask during a dielectric etch 408 that further transfers the line pattern 415 into the dielectric layer 430 to form the dielectric line cut structures 474.

A metal material 475 is then formed on all surfaces of the dielectric material 473 during a metallization 409 and results in excess metal material 477 on top of the dielectric layer 430. A metal layer 470 that includes separate metal lines 476 is then formed by removing the excess metal material 477 during a planarization 419 (e.g., a CMP process). The pattern of the metal layer 470 includes metal cuts 484 that separate respective metal lines 476 into a first metal segment 488 and a second metal segment 487. As before, the mandrel metal lines 478 do not include any metal cuts 484.

FIG. 5 schematically illustrates an example process including a metal cut formed in a metal line using a line cut structure formed from a sidewall spacer where two cut windows are formed through a resist layer overlying a line pattern in accordance with embodiments of the invention. The process of FIG. 5 may be a specific implementation of other processes described herein such as the processes of FIG. 1A-3C, for example. Similarly labeled elements may be as previously described.

Referring to FIG. 5, a process 500 begins with a substrate 510 having a window resist layer 560 that has been formed over a line pattern including mandrels 554 and line sidewall spacers 551 separated by spaces exposing a dielectric material 573 of a dielectric layer 530. As may be expected, multiple cut windows may be formed in various implementations of the processes described herein. An example showing two cut windows, a cut window 564 and an additional cut window 569 that exposes portions of spaces 558, is shown here.

The process 500 uses the cut window 564 and the additional cut window 569 to form metal cuts 584 in metal lines formed from a metal material 575 in empty spaces of the dielectric layer 530. The metal cuts 584 separate the metal lines into first metal segments 588 with first line thickness 581 and second metal segments 587 with a second line thickness 582 that is thicker than the first. As shown, the segments that were within a cut window (the first metal segments 588) have the thinner first line thickness 581.

FIG. 6 schematically illustrates an example process including a metal cut formed in a metal line using a line cut structure formed from a sidewall spacer where spacers spanning spaces of a line pattern are formed on two sidewalls of a cut window formed through a resist layer overlying the line pattern in accordance with embodiments of the invention. The process of FIG. 6 may be a specific implementation of other processes described herein such as the processes of FIG. 1A-3C, for example. Similarly labeled elements may be as previously described.

Referring to FIG. 6, a process 600 begins with a substrate 610 having a window resist layer 660 that has been formed over a line pattern including mandrels 654 and line sidewall spacers 651 separated by spaces exposing a dielectric material 673 of a dielectric layer 630. Another possible use of the cut windows usable in various implementations of the processes described herein is to utilize both sides of the cut window to form metal cuts. An example with a cut window 664 that exposes portions of spaces 658 and has sidewalls spanning spaces on both sides of the cut window 664 is shown here.

The process 600 uses the cut window 664 to form metal cuts 684 in metal lines formed from a metal material 675 in empty spaces of the dielectric layer 630. The metal cuts 684 separate the metal lines into first metal segments 688 with a first line thickness 681 and second metal segments 687 with a second line thickness 682 that is thicker than the first. Because there are two metal cuts in a single line, there are three segments, with the middle region that was in the cut window 664 being thinner.

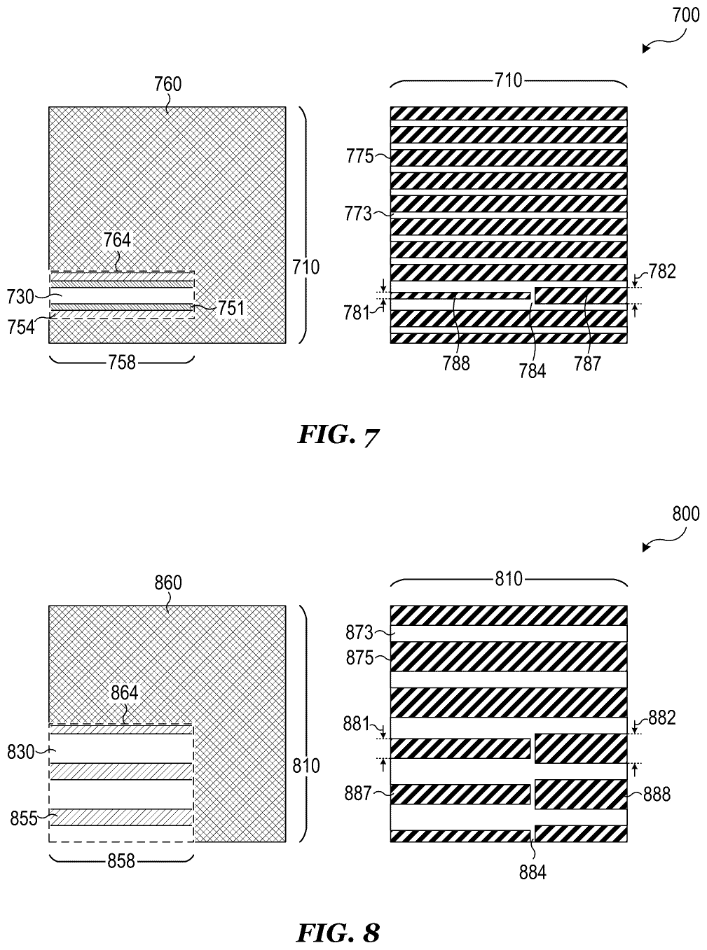

FIG. 7 schematically illustrates an example process including a metal cut formed in a metal line using a line cut structure formed from a sidewall spacer where a cut window spanning only one space of a line pattern is formed through a resist layer overlying the line pattern in accordance with embodiments of the invention. The process of FIG. 7 may be a specific implementation of other processes described herein such as the processes of FIG. 1A-3C, for example. Similarly labeled elements may be as previously described.

Referring to FIG. 7, a process 700 begins with a substrate 710 having a window resist layer 760 that has been formed over a line pattern including mandrels 754 and line sidewall spacers 751 separated by spaces exposing a dielectric material 773 of a dielectric layer 730. It is also possible that cut windows in various implementations of the processes described herein only span a single space at a time (although this may require the window resist layer to have higher resolution capabilities). An example with a cut window 764 that exposes a portion of a space 758 is shown here. The process 700 uses the cut window 764 to form a metal cut 784 in a metal line formed from a metal material 775. The metal cut 784 separates the metal line into a first metal segment 788 with a first line thickness 781 and second metal segment 787 with a second line thickness 782 that is thicker than the first. Since there is only one metal cut, there is only one metal segment with the first line thickness 781.

FIG. 8 schematically illustrates an example process including a metal cut formed in a metal line using a line cut structure formed from a sidewall spacer where a cut window is formed through a resist layer overlying a line pattern that does not include preexisting sidewalls spacers in accordance with embodiments of the invention. The process of FIG. 8 may be a specific implementation of other processes described herein such as the processes of FIG. 1A-3C, for example. Similarly labeled elements may be as previously described.

Referring to FIG. 8, a process 800 begins with a substrate 810 having a window resist layer 860 that has been formed over a line pattern including lines 855 separated by spaces exposing a dielectric material 873 of a dielectric layer 830. While it may be advantageous in many situations to use line sidewalls spacers to increase the number of metal lines in a metal layer, this not a requirement of implementations of the processes described herein. For example, the substrate 810 does not include line sidewall spacers. A cut window 864 that exposes portions of spaces 858 is formed in the window resist layer 860 as before. The process 800 uses the cut window 864 to form metal cuts 884 in metal lines formed from a metal material 875 in empty spaces of the dielectric layer 830. The metal cuts 884 separate the metal lines into first metal segments 888 with a first line thickness 881 and second metal segments 887 with a second line thickness 882 that is thicker than the first. Because there were no mandrels, the metal lines are thicker than they otherwise would be and the metal cuts 884 may be made through adjacent metal lines, as shown.

FIG. 9 illustrates a flowchart of an example method of forming a line cut structure that may be implemented by processes including a line cut structure spanning a space of a line pattern formed from a sidewall spacer of a window through a resist layer in accordance with embodiments of the invention. The method of FIG. 9 may be combined with other methods and be implemented using the processes described herein. For example, the method of FIG. 9 may be combined with any of the embodiments of FIG. 1A-8 and 10. Although shown in a logical order, the arrangement and numbering of the steps of FIG. 9 are not intended to be limited. The method steps of FIG. 9 may be performed in any suitable order or concurrently with one another as may be apparent to a person of skill in the art.

Referring to FIG. 9, a method 900 of forming a line cut structure begins with a substrate in an initial state 993 where a resist layer has been formed on a line pattern in or on the substrate and resist material has been removed from the resist layer to form the cut window, which extends through the resist layer exposing a portion of the line pattern. During a conformal deposition 904, a conformal layer is deposited on at least one sidewall of the cut window. The conformal layer is also conformally deposited through the cut window on a portion of a space separating lines of the line pattern. The at least one sidewall spans the space (i.e., the sidewall extends through the entire width of space forming a first space segment and a second space segment separated by the sidewall).

In a cut spacer etch 905, the conformal layer is etched from horizontal surfaces of the substrate leaving a cut sidewall spacer on the at least one sidewall. In particular, other surfaces of the substrate are again exposed, including the horizontal surfaces of the line pattern (i.e., the tops of lines and the bottoms of spaces) and the resist material. The resist layer is then removed from the substrate (including from between lines of the line pattern) during a resist removal process 906 to form the line cut structure from the cut sidewall spacer.

After the resist removal process 906, the line cut structure stands alone spanning a space of the line pattern. The line cut structure may then be used to form other structures, if desired, during subsequent processing steps, such as those discussed in the foregoing and in the following process described in reference to FIG. 10.

FIG. 10 illustrates a flowchart of an example method of forming a metal cut that may be implemented by processes including a line cut structure spanning a space of a line pattern formed from a sidewall spacer of a window through a resist layer in accordance with embodiments of the invention. The method of FIG. 10 may be combined with other methods and be implemented using the processes described herein. For example, the method of FIG. 10 may be combined with any of the embodiments of FIG. 1A-9. Although shown in a logical order, the arrangement and numbering of the steps of FIG. 10 are not intended to be limited. The method steps of FIG. 10 may be performed in any suitable order or concurrently with one another as may be apparent to a person of skill in the art.

Referring to FIG. 10, a method 1000 of forming a metal cut includes a conformal deposition 1004 (e.g., an ALD process) during which a conformal layer is deposited on at least one sidewall of a cut window in a resist layer. The conformal layer is also conformally deposited through the cut window on a portion of a space separating lines of a line pattern formed in or on a substrate. The at least one sidewall spans the space. In a cut spacer etch 1005, the conformal layer is etched from horizontal surfaces of the substrate leaving a cut sidewall spacer on the at least one sidewall. The resist layer is then removed from the substrate (including from between lines of the line pattern) during a resist removal process 1006 to form the line cut structure from the cut sidewall spacer.

While the method 1000 may begin with the conformal deposition 1004 (similar to the method 900 of FIG. 9, for example) the method 1000 may also include the formation of the cut window. For example, the method 1000 may being with the substrate in an initial state 1090 where the line pattern has been formed in or on a substrate and overlies a dielectric layer. For example, the line pattern may include lines that are a single material, or lines that include more than one material, such as mandrel with line sidewall spacers formed thereon. During a resist formation step 1001, a resist stack may be formed over the line pattern. The resist stack may include a resist layer underlying an etch stop layer and an additional resist material overlying the etch stop layer. The additional resist material may be removed from above a cut window during a resist develop 1002. Then, the opening in the additional resist material may be transferred to the resist layer by etching the resist layer for form the cut window during a window etch 1003 using the remaining additional resist material as an etch mask.

After the line cut structure has been formed from the cut sidewalls spacer during the resist removal process 1006 (e.g., an ashing process), the dielectric layer may be etched during a dielectric etch 1008 transfer the line pattern and the line cut structure into the dielectric layer and form a dielectric line cut structure. When the lines of the line pattern include line sidewall spacers formed on mandrels, the mandrels may be removed leaving behind the line sidewall spacers and the line cut structure before etching the dielectric layer (during a mandrel pull 1007).

In some cases, the line pattern may be transferred directly into the dielectric layer while in other cases, the dielectric etch 1008 may include a hardmask etch 1018 during which a hardmask layer is first etched to transfer the line pattern and the line cut structure into the hardmask layer and then the hardmask layer is used as an etch mask while etching the dielectric layer.

After the line pattern has been transferred into the dielectric layer forming the dielectric line cut structure, a metal layer is formed in the dielectric layer during metallization 1009 and the dielectric line cut structure forms the metal cut in a metal line of the metal layer (which may include other metal lines with and without metal cuts). In some embodiments, the metallization 1009 involves metallizing surfaces of the dielectric layer (including top surfaces) to deposit a metal material in and over the dielectric layer resulting in excess material being on top of the dielectric layer. In this case a planarization 1019 (e.g., a CMP process) may be performed to remove excess metal material over the dielectric layer planarize the metal material and the dielectric layer and form the metal layer (with separate metal lines).

Example embodiments of the invention are summarized here. Other embodiments can also be understood from the entirety of the specification as well as the claims filed herein.
Example 1. A method of forming a line cut structure in a space separating lines of a line pattern formed in or on a substrate, the method including: conformally depositing a conformal layer on at least one sidewall of a cut window in a resist layer and through the cut window on a portion of the space, the at least one sidewall spanning the space; etching the conformal layer from horizontal surfaces of the substrate leaving a cut sidewall spacer on the at least one sidewall; and removing the resist layer to form the line cut structure from the cut sidewall spacer.
Example 2. The method of example 1, further including: forming a resist stack over the line pattern before conformally depositing the conformal layer, the resist stack including an additional resist material overlying an etch stop layer overlying the resist layer; removing the additional resist material from above the cut window; and etching the resist layer to form the cut window using the remaining additional resist material as an etch mask.
Example 3. The method of example 2, where the additional resist material is an UV resist material.
Example 4. The method of one of examples 1 to 3, further including: etching a dielectric layer to transfer the line pattern and the line cut structure into the dielectric layer forming a dielectric line cut structure; and forming a metal layer including a metal line in the dielectric layer, the dielectric line cut structure forming a metal cut in the metal line.
Example 5. The method of example 4, where a thickness of the metal cut is substantially the same as a thickness of the line cut structure.
Example 6. The method of one of examples 1 to 5, where conformally depositing the conformal layer includes an ALD process.
Example 7. The method of one of examples 1 to 6, where the line pattern includes mandrels and line sidewall spacers formed on sidewalls of the mandrels, the line sidewall spacers having a different chemical composition than the cut sidewall spacer.
Example 8. A method of forming a metal cut in a metal line, the method including: conformally depositing, using an ALD process, a conformal layer on at least one sidewall of a cut window in a resist layer and through the cut window on a portion of a space separating lines of a line pattern formed in or on a substrate, the at least one sidewall spanning the space; etching the conformal layer from horizontal surfaces of the substrate leaving a cut sidewall spacer on the at least one sidewall; removing the resist layer to form a line cut structure from the cut sidewall spacer; etching a dielectric layer to transfer the line pattern and the line cut structure into the dielectric layer forming a dielectric line cut structure; and forming a metal layer including the metal line in the dielectric layer, the dielectric line cut structure forming the metal cut in the metal line.
Example 9. The method of example 8, where a thickness of the metal cut is substantially the same as a thickness of the line cut structure.
Example 10. The method of one of examples 8 and 9, forming a resist stack over the line pattern before conformally depositing the conformal layer, the resist stack including an additional resist material overlying an etch stop layer overlying the resist layer; removing the additional resist material from above the cut window; and etching the resist layer to form the cut window using the remaining additional resist material as an etch mask.
Example 11. The method of example 10, where the additional resist material is an UV resist material.
Example 12. The method of one of examples 8 to 11, further including: removing mandrels of the line pattern leaving line sidewall spacers of the line pattern and the line cut structure before etching the dielectric layer, where etching the dielectric layer includes transferring the line sidewall spacers of the line pattern and the line cut structure into the dielectric layer.
Example 13. The method of example 12, where the line sidewall spacers have a different chemical composition than the cut sidewall spacer.
Example 14. The method of one of examples 8 to 13, further including: etching a hardmask layer before etching the dielectric layer to transfer the line pattern and the line cut structure into the hardmask layer, the hardmask layer being used as an etch mask while etching the dielectric layer.
Example 15. The method of one of examples 8 to 14, where forming the metal layer includes: metallizing surfaces of the dielectric layer to deposit a metal material in and over the dielectric layer; and planarizing the metal material and the dielectric layer to remove excess metal material over the dielectric layer and form the metal layer.
Example 16. An integrated circuit including: a substrate including a device layer; a metal layer formed over the device layer, the metal layer including a plurality of metal lines separated by dielectric material; and a dielectric line cut structure forming a metal cut dividing a metal line of the plurality of metal lines into a first metal segment having a first line thickness, and a second metal segment having a second line thickness that is less than the first line thickness.
Example 17. The integrated circuit of example 16, where a T2T CD of the metal cut is less than about 10 nm.
Example 18. The integrated circuit of one of examples 16 and 17, further including: one or more additional dielectric line cut structures forming one or more additional metal cuts dividing the metal line or one or more additional metal lines into metal line segments.
Example 19. The integrated circuit of example 18, where a T2T CD variation of the metal cut and the one or more additional metal cuts is less than about 1 nm.
Example 20. The integrated circuit of one of examples 18 and 19, where the metal cut and the one or more additional metal cuts are disposed in a plurality of metal lines of the metal layer, every other metal line of the plurality of metal lines having no metal cuts.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a line cut structure in a space separating lines of a line pattern formed in or on a substrate, the method comprising:
conformally depositing a conformal layer on at least one sidewall of a cut window in a resist layer and through the cut window on a portion of the space, the at least one sidewall spanning the space;
etching the conformal layer from horizontal surfaces of the substrate leaving a cut sidewall spacer on the at least one sidewall; and
removing the resist layer to form the line cut structure from the cut sidewall spacer.

2. The method of claim 1, further comprising:
forming a resist stack over the line pattern before conformally depositing the conformal layer, the resist stack comprising an additional resist material overlying an etch stop layer overlying the resist layer;
removing the additional resist material from above the cut window; and
etching the resist layer to form the cut window using the remaining additional resist material as an etch mask.

3. The method of claim 2, wherein the additional resist material is an ultraviolet (UV) resist material.

4. The method of claim 1, further comprising:
etching a dielectric layer to transfer the line pattern and the line cut structure into the dielectric layer forming a dielectric line cut structure; and
forming a metal layer comprising a metal line in the dielectric layer, the dielectric line cut structure forming a metal cut in the metal line.

5. The method of claim 4, wherein a thickness of the metal cut is substantially the same as a thickness of the line cut structure.

6. The method of claim 1, wherein conformally depositing the conformal layer comprises an atomic layer deposition (ALD) process.

7. The method of claim 1, wherein the line pattern comprises mandrels and line sidewall spacers formed on sidewalls of the mandrels, the line sidewall spacers having a different chemical composition than the cut sidewall spacer.

8. A method of forming a metal cut in a metal line, the method comprising:
conformally depositing, using an atomic layer deposition (ALD) process, a conformal layer on at least one sidewall of a cut window in a resist layer and through the cut window on a portion of a space separating lines of a line pattern formed in or on a substrate, the at least one sidewall spanning the space;
etching the conformal layer from horizontal surfaces of the substrate leaving a cut sidewall spacer on the at least one sidewall;
removing the resist layer to form a line cut structure from the cut sidewall spacer;
etching a dielectric layer to transfer the line pattern and the line cut structure into the dielectric layer forming a dielectric line cut structure; and
forming a metal layer comprising the metal line in the dielectric layer, the dielectric line cut structure forming the metal cut in the metal line.

9. The method of claim 8, wherein a thickness of the metal cut is substantially the same as a thickness of the line cut structure.

10. The method of claim 8,
forming a resist stack over the line pattern before conformally depositing the conformal layer, the resist stack comprising an additional resist material overlying an etch stop layer overlying the resist layer;
removing the additional resist material from above the cut window; and
etching the resist layer to form the cut window using the remaining additional resist material as an etch mask.

11. The method of claim 10, wherein the additional resist material is an ultraviolet (UV) resist material.

12. The method of claim 8, further comprising:
removing mandrels of the line pattern leaving line sidewall spacers of the line pattern and the line cut structure before etching the dielectric layer,
wherein etching the dielectric layer comprises transferring the line sidewall spacers of the line pattern and the line cut structure into the dielectric layer.

13. The method of claim 12, wherein the line sidewall spacers have a different chemical composition than the cut sidewall spacer.

14. The method of claim 8, further comprising:
etching a hardmask layer before etching the dielectric layer to transfer the line pattern and the line cut structure into the hardmask layer, the hardmask layer being used as an etch mask while etching the dielectric layer.

15. The method of claim 8, wherein forming the metal layer comprises:
metallizing surfaces of the dielectric layer to deposit a metal material in and over the dielectric layer; and
planarizing the metal material and the dielectric layer to remove excess metal material over the dielectric layer and form the metal layer.

16. An integrated circuit comprising:
a substrate comprising a device layer;
a metal layer formed over the device layer, the metal layer comprising a plurality of metal lines separated by dielectric material; and
a dielectric line cut structure forming a metal cut dividing a metal line of the plurality of metal lines into a first metal segment having a first line thickness, and a second metal segment having a second line thickness that is less than the first line thickness.

17. The integrated circuit of claim 16, wherein a tip-to-tip (T2T) critical dimension (CD) of the metal cut is less than about 10 nm.

18. The integrated circuit of claim 16, further comprising:
one or more additional dielectric line cut structures forming one or more additional metal cuts dividing the metal line or one or more additional metal lines into metal line segments.

19. The integrated circuit of claim 18, wherein a tip-to-tip (T2T) critical dimension (CD) variation of the metal cut and the one or more additional metal cuts is less than about 1 nm.

20. The integrated circuit of claim 18, wherein the metal cut and the one or more additional metal cuts are disposed in a plurality of metal lines of the metal layer, every other metal line of the plurality of metal lines having no metal cuts.
